(19) United States
(12) Patent Application Publication
(10) Pub. No.: US 2024/0035161 A1
(43) Pub. Date: Feb. 1, 2024

(54) ACTIVELY CONTROLLED PRE-HEAT RING FOR PROCESS TEMPERATURE CONTROL

(71) Applicant: Applied Materials, Inc., Santa Clara, CA (US)

(72) Inventors: Zhepeng CONG, San Jose, CA (US); Ashur J. ATANOS, San Jose, CA (US); Tao SHENG, Santa Clara, CA (US); Nimrod SMITH, Cupertino, CA (US); Vinh N. TRAN, San Jose, CA (US)

(21) Appl. No.: 17/873,842

(22) Filed: Jul. 26, 2022

(51) Int. Cl. C23C 16/458; C23C 16/48; H05B 1/02; H05B 3/00; H05B 3/06

(52) U.S. Cl. CPC C23C 16/4585; C23C 16/482; H05B 1/0233; H05B 3/0047; H05B 3/06

(57) ABSTRACT

An apparatus for heating a gas is described. The apparatus is a pre-heat ring and heater assembly positioned in a deposition chamber, such as an epitaxial deposition chamber. The pre-heat ring has a first portion configured to be heated using one or more heaters. The one or more heaters are disposed through a sidewall of the process volume beneath the pre-heat ring and are configured to heat the pre-heat ring so that gas flowed over the pre-heat ring is also heated before being flowed over a substrate. The one or more heaters may include two heaters disposed at distal ends of the first portion of the pre-heat ring. One or more temperature sensors are also configured to measure a temperature of the pre-heat ring.

### BACKGROUND

### Field

Embodiments of the present disclosure generally relate to a methods of processing a substrate. More specifically, the embodiments described herein relate to methods of heating a pre-heat ring and precursor within a semiconductor processing chamber.

### Description of the Related Art

Semiconductor substrates are processed for a wide variety of applications, including the fabrication of integrated devices and micro-devices. One method of substrate processing includes depositing a material, such as a dielectric material or a conductive metal, on an upper surface of the substrate in a processing chamber. For example, epitaxy is a deposition process that grows a thin, ultra-pure layer, usually of silicon or germanium on a surface of a substrate. The material may be deposited in a lateral flow chamber by flowing a process gas parallel to the surface of a substrate positioned on a support and thermally decomposing the process gas to deposit a material from the process gas onto the substrate surface.

During epitaxial deposition, a process gas is flowed over a substrate and a top surface of a susceptor. The process gas temperature is utilized to form a film or layer on the substrate. The temperature of the process gas between the front end and back end of a substrate during processing varies. The non-uniformity of the process gas causes non-uniform deposition along the length of the substrate. The non-uniform deposition is accounted for through rotation of the substrate, but significant amounts of precursor gas are still lost and growth rates at the edges of the substrate are still different from growth rates in the center of the substrate.

Therefore, there is a need for improved temperature control of process gases within a processing chamber.

### SUMMARY

In one embodiment, a process chamber, configured for use during semiconductor processing, includes a chamber body comprising a plurality of gas inlets on a first side of the chamber body and one or more exhaust outlets on a second side of the chamber body opposite the first side; a substrate support disposed within a process volume of the chamber body; and a pre-heat ring assembly disposed between the plurality of gas inlets and the substrate support. The pre-heat ring assembly includes: a pre-heat ring; one or more heaters disposed adjacent to the pre-heat ring; and one or more temperature sensors disposed adjacent to the pre-heat ring.

In another embodiment, a pre-heat ring assembly, configured for use within a semiconductor processing chamber, includes a pre-heat ring comprising a first pre-heat ring section and a second pre-heat ring section; one or more temperature sensors coupled to the first pre-heat ring section; and two or more heaters coupled to and configured to heat the first pre-heat ring section. The two or more heaters including a heater casing; a reflector disposed within the heater casing and forming a front heater volume; and a heating element disposed within the front heater volume.

A heater insert, configured to heat a pre-heat ring within a semiconductor processing chamber, including a heater casing comprising: a transmissive portion; an opaque portion coupled to a distal end of the transmissive portion; and a heater base coupled to a distal end of the transmissive portion opposite the transmissive portion, such that the opaque portion intersects a contact surface of the heater base and the contact surface has one or more grooves disposed therein; a reflector disposed within the heater casing and forming a front heater volume and a back heater volume; and a heating element disposed within the front heater volume and within the transmissive portion of the heater casing.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 is a schematic cross-sectional side view of a process chamber, according to embodiments of the present disclosure.

FIG. 2A is a schematic cross-sectional plan view of the process chamber through a first plane, according to embodiments of the present disclosure.

FIG. 2B is a schematic cross-sectional plan view of the process chamber through a second plane, according to embodiments of the present disclosure.

FIG. 3 is a schematic partial cross-sectional view of a pre-heat ring assembly of the process chamber of FIG. 1, according to embodiments of the present disclosure.

FIG. 4A is a schematic partial cross-sectional view of a heater within the process chamber of FIG. 1, according to one embodiment of the present disclosure.

FIG. 4B is a schematic partial cross-sectional view of a heater within the process chamber of FIG. 1, according to another embodiment of the present disclosure.

FIG. 4C is a schematic partial cross-sectional view of a heater within the process chamber of FIG. 1, according to yet another embodiment of the present disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure is directed towards heating apparatus for heating a pre-heat ring within a semiconductor processing chamber. The heating apparatus and pre-heat ring described herein are specifically directed towards use within a deposition chamber, such as an epitaxial deposition chamber. The heater is configured to provide additional temperature control to a pre-heat ring within the deposition chamber and therefore enable increased gas/precursor activation towards a leading edge of the substrate adjacent to gas injection into the process volume.

A sensor, such as a pyrometer or other temperature sensor, may be mounted on or within one of the pre-heat ring or the heater itself to measure the temperature of the pre-heat ring or the heater. Measuring the temperature of the pre-heat ring or the heater enables the temperature control of the pre-heat ring to be monitored in real time and enables adjustment of the heater power to adjust epitaxial growth rates on the substrate. Monitoring the temperature of the pre-heat ring further enables more repeatable process results as the power applied to the one or more heaters within the pre-heat ring may be adjusted.

It has been found that precursors and process gases react with the surface of the substrate to form a film above a determined temperature and the rate of reaction increases with an increase in the temperature of the precursor or process gas. The precursors and process gases are often heated as the precursors and/or process gases pass over the substrate. Therefore, higher temperature substrates often produce higher growth rates and therefore higher substrate throughputs. However, the material composition and structures formed on the substrate sometimes limit the maximum temperature which is applied to the substrate before causing damage or warpage to the substrate. The temperature of the substrate is a major factor in the process characteristics, such as the precursor selection, throughput, growth rate, and growth uniformity. The use of a pre-heat ring assists in increasing the temperature of the precursors/process gases before the precursors/process gases are flowed over the substrate. The pre-heat ring further is formed of a material with less temperature limitations and therefore may be heated to a higher temperature than the substrate or substrate support. Pre-heating the pre-heat ring to a higher temperature increases the temperature and therefore reaction rate of the precursors/process gases before the precursors/process gases pass over the substrate.

Additionally, the inventors have found that without active heating of the pre-heat ring, the temperature of the pre-heat ring is often about 50° C. to about 100° C. less than the temperature of the substrate or the substrate support on which the substrate is positioned. It has also been found that stabilization of the temperature of the pre-heat ring often takes longer than the temperature stabilization of the substrate support. The use of one or more heaters within the pre-heat ring or directly adjacent to the pre-heat ring enables improved control of the temperature of the pre-heat ring, such that the temperature of the pre-heat ring is able to be controlled independently of the temperature of the substrate or substrate support and other components within the process chamber. The temperature may further be stabilized quickly and with greater repeatability to enable repeatable thermal chemical vapor deposition (CVD) processes.

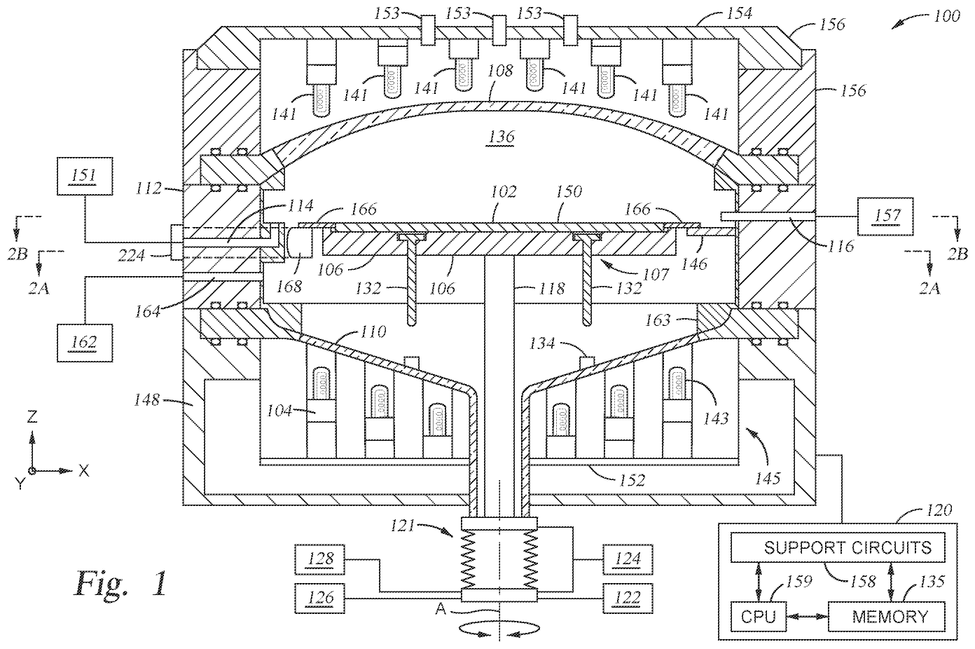

FIG. 1 is a schematic cross-sectional side view of a process chamber 100, such as a deposition chamber, such as an epitaxial deposition chamber. The process chamber 100 is utilized to grow an epitaxial film on a substrate, such as the substrate 102. The process chamber 100 creates a cross-flow of precursors across the top surface 150 of the substrate 102.

The process chamber 100 includes an upper body 156, a lower body 148 disposed below the upper body 156, a flow module 112 disposed between the upper body 156 and the lower body 148. The upper body 156, the flow module 112, and the lower body 148 form a chamber body. Disposed within the chamber body is a substrate support 106, an upper transmissive window 108, a lower transmissive window 110, a plurality of upper lamps 141, and a plurality of lower lamps 143. As shown, the controller 120 is in communication with the process chamber 100 and is used to control processes, such as those described herein. The substrate support 106 is disposed between the upper transmissive window 108 and the lower transmissive window 110. The plurality of upper lamps 141 are disposed between the upper transmissive window 108 and a lid 154. The lid 154 includes a plurality of sensors 153 disposed therein for measuring the temperature within the process chamber 100. The plurality of lower lamps 143 are disposed between the lower transmissive window 110 and a floor 152. The plurality of lower lamps 143 form a lower lamp assembly 145.

A process volume 136 is formed between the upper transmissive window 108 and the lower transmissive window 110. The upper transmissive window 108 may have a dome shape and may be referred to as an upper dome. The upper transmissive window 108 has an upper dome portion, sometimes referred to as a central window portion in embodiments where the upper dome portion is not dome-shaped, and a support ring. The support ring is coupled to an outer edge of the upper dome portion and is disposed between the upper body 156 and the flow module 112. The lower transmissive window 110 may also be a dome shape, such that the lower transmissive window 110 has a lower dome portion, sometimes referred to as a central window portion in embodiments where the lower dome portion is not dome-shaped, with a central opening in the center of the lower dome portion for a shaft 118 of the substrate support 106 to be disposed therethrough. The lower dome portion of the lower transmissive window 110 is connected to a support ring at an outer edge of the lower dome portion. The support ring is disposed between the lower body 148 and the flow module 112.

The process volume 136 has the substrate support 106 disposed therein. The substrate support 106 includes a top surface on which the substrate 102 is disposed. The substrate support 106 is attached to the shaft 118. The shaft is connected to a motion assembly 121. The motion assembly 121 includes one or more actuators and/or adjustment devices that provide movement and/or adjustment of the shaft 118 and/or the substrate support 106 within the process volume 136. The motion assembly 121 includes a rotary actuator 122 that rotates the shaft 118 and/or the substrate support 106 about a longitudinal axis A of the process chamber 100. The motion assembly 121 further includes a vertical actuator 124 to lift and lower the substrate support 106 in the z-direction. The motion assembly includes a tilt adjustment device 126 that is used to adjust the planar orientation of the substrate support 106 and a lateral adjustment device 128 that is used to adjust the position of the shaft 118 and the substrate support 106 side to side within the process volume 136.

The substrate support 106 may include lift pin holes 107 disposed therein. The lift pin holes 107 are sized to accommodate a lift pin 132 for lifting of the substrate 102 from the substrate support 106 either before or after a deposition process is performed. The lift pins 132 may rest on lift pin stops 134 when the substrate support 106 is lowered from a processing position to a transfer position.

The flow module 112 includes a plurality of process gas inlets 114, a plurality of purge gas inlets 164, and one or more exhaust gas outlets 116. The plurality of process gas inlets 114 and the plurality of purge gas inlets 164 are disposed on the opposite side of the flow module 112 from the one or more exhaust gas outlets 116. One or more flow guides 146 are disposed below the plurality of process gas inlets 114 and the one or more exhaust gas outlets 116. The flow guide 146 is disposed above the purge gas inlets 164. A liner 163 is disposed on the inner surface of the flow module 112 and protects the flow module 112 from reactive gases used during deposition processes. The process gas inlets 114 and the purge gas inlets 164 are positioned to flow a gas parallel to the top surface 150 of a substrate 102 disposed within the process volume 136. The process gas inlets 114 are fluidly connected to a process gas source 151. The purge gas inlets 164 are fluidly connected to a purge gas source 162. The one or more exhaust gas outlets 116 are fluidly connected to an exhaust pump 157. Each of the process gas source 151 and the purge gas source 162 may be configured to supply one or more precursors or process gases into the process volume 136.

One or more heaters 168 are disposed adjacent to a pre-heat ring 166 within the process chamber 100. The pre-heat ring 166 is a ring which is configured to be disposed around an outer edge of the substrate 102, such that the pre-heat ring 166 may overlap an outermost portion of the substrate support 106 and rest on the substrate support 106 surrounding the substrate 102. The pre-heat ring 166 may be formed of one or more parts. The pre-heat ring 166 has a top surface which is parallel to the direction of gas flow across the top surface 150 of the substrate 102 and the substrate support 106.

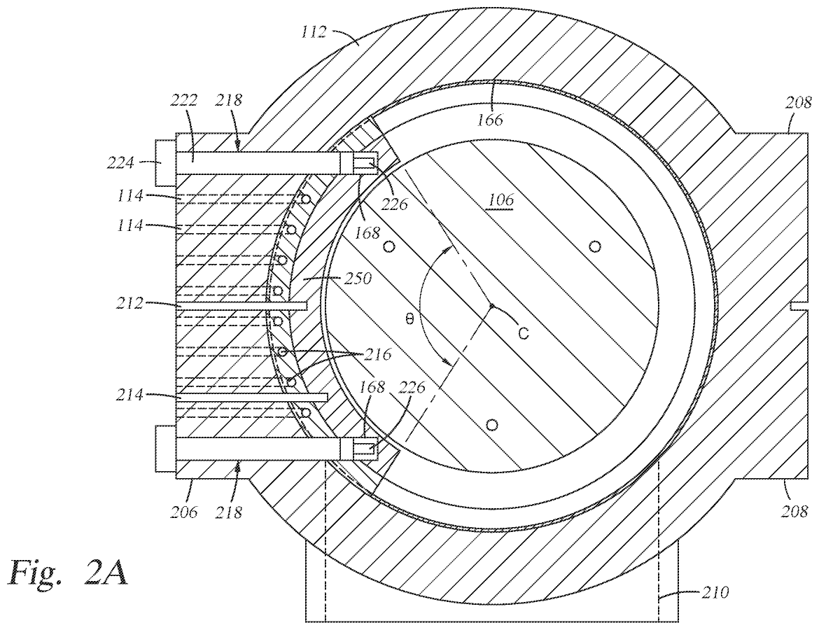

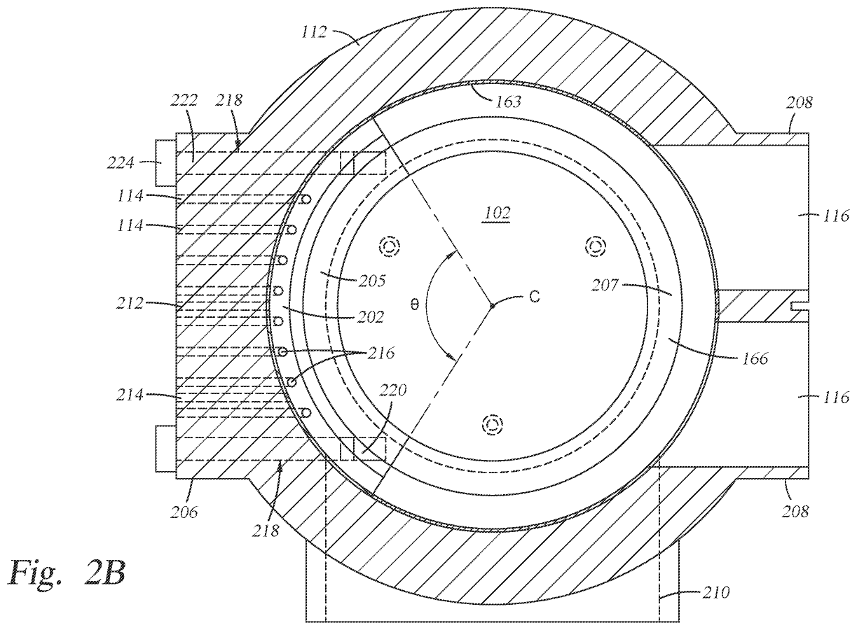

The one or more heater 168 are disposed beneath the pre-heat ring 166, such that the one or more heaters 168 are contacting the pre-heat ring 166 and formed through a wall of the flow module 112 and the liner 163. The one or more heaters 168 are disposed between the pre-heat ring 166 and the lower transmissive window 110. The one or more pre-heat rings 168 may be disposed within a heating block, such as the heater block 250 of FIG. 2A, which extends under a portion of the pre-heat ring 166. The one or more pre-heat rings 166 may rest on top of the heating block 250. The one or more heaters 168 extend inward from the flow module 112 and the liner 163 into the process volume 136.

FIG. 2A is a schematic cross-sectional plan view of the process chamber through a first plane 2A-2A. The first plane 2A-2A passes through the heaters 168 and the substrate support 106, but beneath the pre-heat ring 166. As shown in FIG. 2A, the heaters 168 are disposed through openings within an inject assembly 206 and the flow module 112, such that a heater insert 218 is disposed through the inject assembly 206 and the flow module 112. The inject assembly 206 is a horizontal gas flow injector, such that gas is configured to be injected over a top surface 150 of the substrate 102. The plurality of process gas inlets 114 are disposed through the inject assembly 206 and configured to provide a distributed gas flow horizontally over the substrate support 106. One or more temperature sensors 212, 214 are also disposed through the inject assembly 206 and are configured to measure a temperature of the pre-heat ring 166 and/or the heating block 250 through which the heaters 168 extend.

The inject assembly 206 is disposed on a first side of the flow module 112 and may be either continuously formed or separable from the flow module 112. Across from the inject assembly 206 on an opposite side of the flow module 112 is an exhaust assembly 208 which includes the exhaust gas outlets 116 disposed therethrough. A substrate transfer opening 210 is further disposed through the wall of the flow module 112. The substrate transfer opening 210 is sized to enable a substrate to pass therethrough. The substrate transfer opening 210 is between the inject assembly 206 and the exhaust assembly 208.

The process gas inlets 114 include an angled portion 216 disposed through the liner 163 and/or the inject assembly 206. In the embodiment of FIG. 2A, the angled portion 216 is a vertical portion and extends normally compared to the top surface 150 of the substrate 102. In some embodiments, the process gas inlets 114 may be heated using one or more heating elements disposed within the flow module 112. However, the temperature of the process gas being flowed through the process gas inlets 114 is limited to reduce unintentional deposition and film formation within the process gas inlets 114 themselves. Therefore, the use of the pre-heat ring 166 enables the temperature of gases and/or precursors are increased between leaving the process gas inlets 114 and flowing over the substrate 102 and the susceptor 106.

The heater insert 218 includes a heater casing 222 and a heater base 224. The heater casing 222 is coupled to the heater base 224. The heater base 224 is coupled to an outside surface of the inject assembly 206 and the flow module 112. The heater base 224 is utilized to secure the heater insert 218 to the outside of the inject assembly 206 and/or the flow module 112 and holds the heater insert 218 in place. The heater base 224 extends outward from the outside surface of the heater insert 218, such that the heater base 224 forms a flange around a distal end of the heater casing 222.

A heating element 226 is disposed at a distal end of the heater casing 222 opposite the heater base 224. The heating element 226 is disposed within a portion of the heater casing 222 where the heater casing 222 is transparent, such as optically transparent. The heating element 226 is configured to heat one or both of the heater block 250 and the pre-heat ring 166. The heating element 226 is electrically coupled to a power source and the controller 120. The power source may be an alternating current or a direct current power source.

The heating elements 226 are disposed within the heating block 250. The heating block 250 may be a partial ring, such that the heating block 250 has an arcuate shape and is disposed beneath a portion of the pre-heat ring 166 and the flow of gas from the inject assembly 206 to the substrate support 106. The heating block 250 may be disposed between two heating elements 226, such that heat from the two heating elements 226 is dispersed along the heating block 250 to enable uniform heating along the length of the heating block 250. The heating block 250 may be a silicon carbide material. The material of the heating block 250 has a thermal conductivity of greater than about 100 W/(m·K), such as greater than about 110 W/(m·K), such as greater than about 120 W/(m·K), such as greater than about 150 W/(m·K). The heating block 250 may contact the underside of the pre-heat ring 166, such that the pre-heat ring 166 rests on the heating block 250.

In the embodiment of FIG. 2A, there are two heaters 168. Each of the two heaters 168 are disposed on opposite sides of the inject assembly 206, such that a first heater 168 is disposed on a first distal end of the inject assembly 206 and a second heater 168 is disposed on a second distal end of the inject assembly 206. The first heater 168 and the second heater 168 are further disposed on opposite ends of the heating block 250. In some embodiments, additional heaters 168 may be disposed between the first heater 168 and the second heater 168.

The temperature sensors 212, 214 are also disposed through the inject assembly 206 and the flow module 112. The temperature sensors 212, 214 extend through the liner 163 and into one of the heating block 250 and/or the pre-heat ring 166. A first temperature sensor 212 is disposed through a central portion of the inject assembly 206 and the heating block 250. A second temperature sensor 214 is disposed adjacent to one of the heaters 168, such that the second temperature sensor 214 measures a temperature near a distal end of the heating block 250/pre-heat ring 166 while the first temperature sensor 212 measures a temperature near a center of the heating block 250/pre-heat ring 166. The temperature sensors 212, 214 may be one or a combination of a pyrometer or a thermocouple.

FIG. 2B is a schematic cross-sectional plan view of the process chamber 100 through a second plane 2B-2B. The second plane 2B-2B is through the flow module 112, but disposed above the pre-heat ring 166 and the substrate support 106 and the substrate 102. As shown in FIG. 2B, the pre-heat ring 166 is split into a first pre-heat ring portion 205 and a second pre-heat ring portion 207. The first pre-heat ring portion 205 is disposed adjacent to the heaters 168 and the heating block 250, such that the heating block 250 contacts the bottom of the first pre-heat ring portion 205. The second pre-heat ring portion 207 is disposed adjacent to the first pre-heat ring portion 205 and completes the pre-heat ring 166. The second pre-heat ring portion 207 has is disposed on top of the one or more flow guides 146 which extend inward from the liner 163. The second pre-heat ring portion 207 forms a majority of the ring and extends around the trailing edge of the substrate support adjacent to the exhaust gas outlets 116. The first pre-heat ring portion 205 circumscribes a first portion of the circumference of the substrate 102 and the substrate support 106. The second pre-heat ring portion 207 circumscribes a second portion of the circumference of the substrate 102 and the substrate support 106.

The first pre-heat ring portion 205 and the second pre-heat ring portion 207 form two distinct arches. Each of the first pre-heat ring portion 205 and the second pre-heat ring portion 207 further have a first end and a second end. The first pre-heat ring portion 205 has a first arc angle θ between a first distal end and a second distal end of less than about 180 degrees, such as less than about 160 degrees, such as less than about 150 degrees, such as less than about 145 degrees, such as less than about 120 degrees, such as less than about 100 degrees. The second pre-heat ring portion 207 has a second arc angle between a first distal end and a second distal end of greater than about 180 degrees, such as greater than about 200 degrees, such as greater than about 210 degrees, such as greater than about 220 degrees, such as greater than about 250 degrees, such as greater than about 260 degrees. Each of the arcs of the first pre-heat ring portion 205 and the second pre-heat ring portion 207 are centered about a central axis C of the substrate support 106.

The separation of the first pre-heat ring portion 205 and the second pre-heat ring portion 207 enables the first pre-heat ring portion 205 and the second pre-heat ring portion 207 to be formed of different materials. The separation of the first pre-heat ring portion 205 and the second pre-heat ring portion 207 further enables the temperature of the first pre-heat ring portion 205 to be better controlled by reducing the amount of heat distributed to the second pre-heat ring portion 207 as a thermal gap is created between the first pre-heat ring portion 205 and the second pre-heat ring portion 207. The thermal gap is formed by either just the separation of the first pre-heat ring portion 205 and the second pre-heat ring portion 207, a gap/space between the first pre-heat ring portion 205 and the second pre-heat ring portion 207, or an insulator disposed between the first pre-heat ring portion 205 and the second pre-heat ring portion 207.

A gas inlet surface 202 is disposed adjacent to the first pre-heat ring portion 205 of the pre-heat ring 166, such that gas from the process gas inlets 114 is directed upwards before being redirected by a portion of the liner 163. In some embodiments, the gas inlet surface 202 may face the substrate support 106, such that the gas inlet surface 202 is perpendicular to the top surface 150 of the substrate 102.

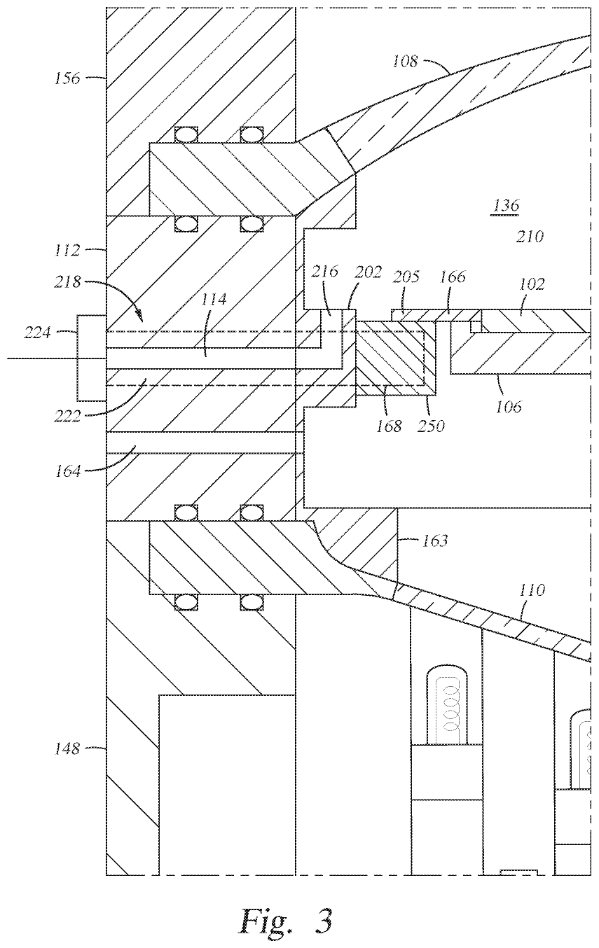

FIG. 3 is a schematic partial cross-sectional view of a pre-heat ring assembly of the process chamber 100 of FIG. 1. The pre-heat ring assembly includes the pre-heat ring 166 and the one or more heaters 168. The pre-heat ring 166 is configured to contact the one or more heaters 168 and/or the heating block 250. The pre-heat ring 166 may further rest on top of the substrate support 106 when the substrate support 106 is in a processing position.

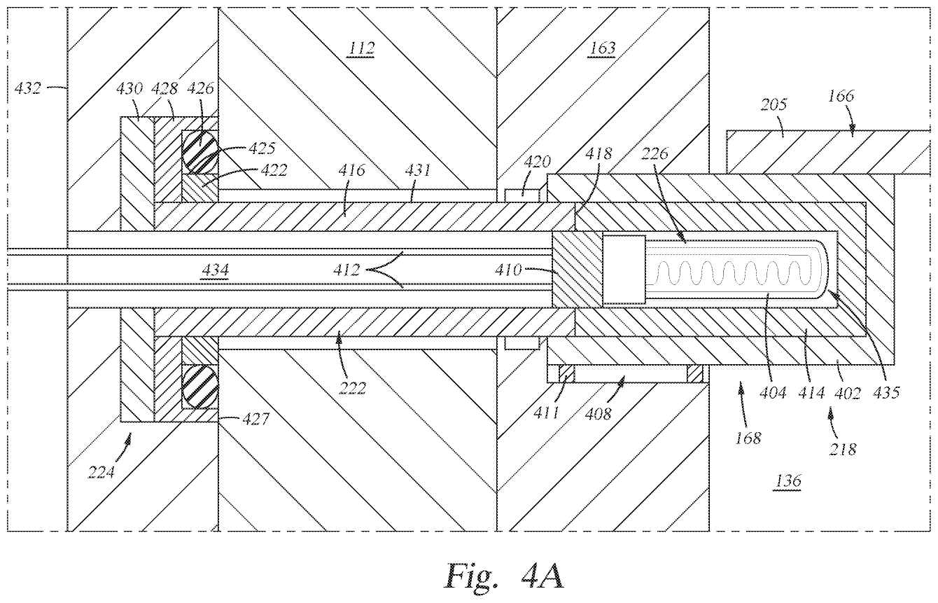

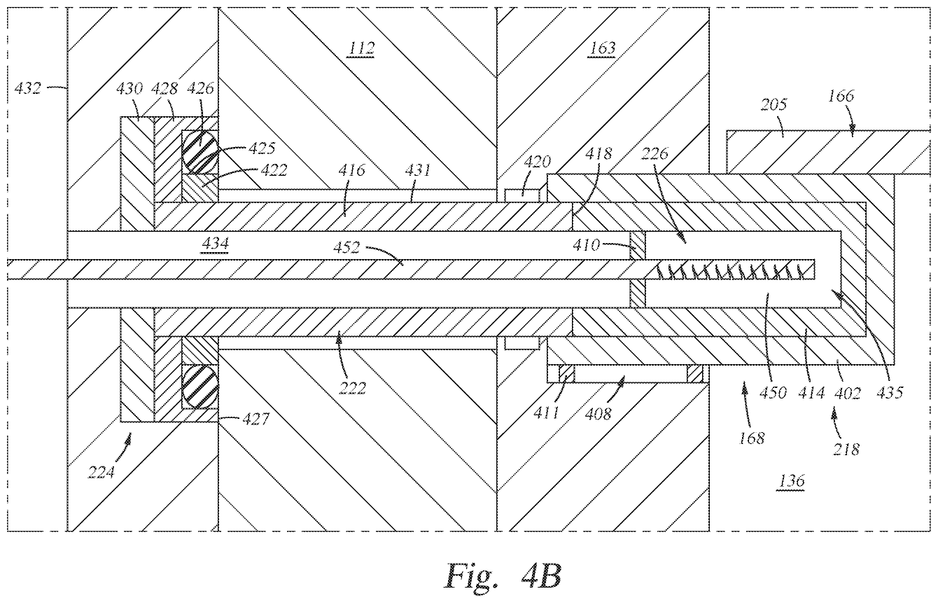

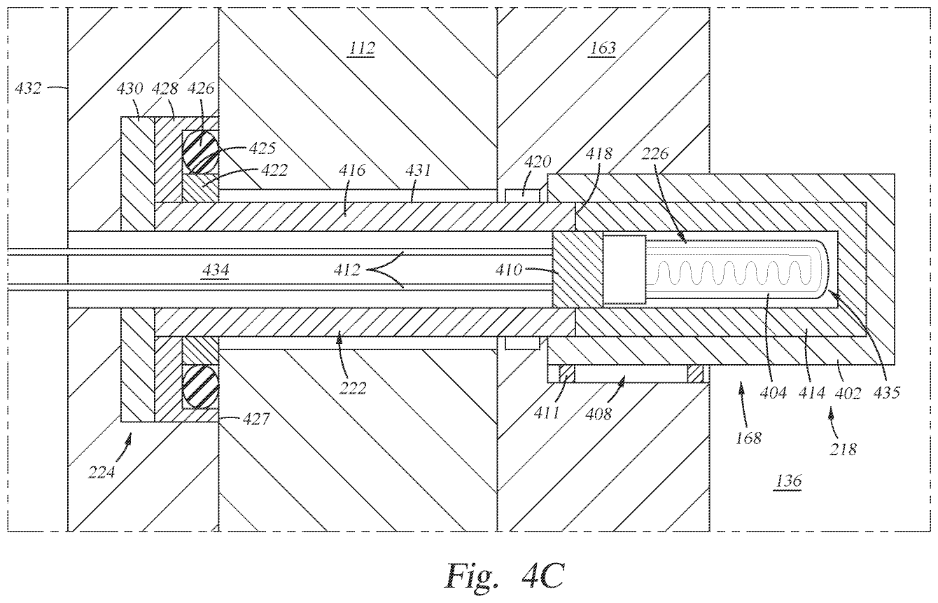

FIG. 4A is a schematic partial cross-sectional view of a heater 168 within the process chamber 100 of FIG. 1. The heater 168 is disposed through both the flow module 112 and the liner 163. The heater 168 extends into the process volume 136. Each of the heaters 168 further include the heater casing 222, a heater insert body 402, the heater base 224, and the heating element 226. The heater casing 222 is disposed at least partially inside of the heater insert body 402, such that the heater insert body 402 is disposed around a portion of the heater insert body 402 which is around the heating element 226.

The heater insert body 402 is disposed within the process volume 136, such that the heater insert body 402 does not extend past at least one of the liner 163 or the flow module 112. The heater insert body 402 may be a portion of the heating block 250, such that the heater insert body 402 is a portion of the heating block 250 which surrounds one of the heater casings 222. The heater insert body 402 may alternatively be a cylindrical body which surrounds an end of the heater casing 222 in which the heating element 226 is disposed. The heater insert body 402 is formed of a highly conductive material, such as a silicon carbide material. The silicon carbide material has reduced interaction with gases within the process volume while still having a high thermal conductivity. The material of the heater insert body 402 has a thermal conductivity of greater than about 100 W/(m·K), such as greater than about 110 W/(m·K), such as greater than about 120 W/(m·K), such as greater than about 150 W/(m·K).

The heater insert body 402 may be thermally isolated from the liner 163, such that one or more separators 411 are disposed between the heater insert body 402 and the liner 163. The one or more separators 411 form a gap 408, which may serve as a thermal gap 408. The one or more separators 411 are thermal isolators, such that the one or more separators 411 are a ceramic or dielectric material.

A seal groove 420 is disposed around a portion of the heater casing 222 within the liner 163. The seal groove 420 is a groove which extends outward from the opening through which the heater casing 222 extends within the liner 163. The seal groove 420 is configured to receive a sealing ring, such that the seal groove 420 enables a sealing ring, such as an o-ring to be disposed therein to reduce or prevent gases from the process volume 136 from extending pas the liner 163 and through the flow module 112 towards an outside volume.

A reflector 410 is disposed within the heater casing 222 and forms a front heater volume 435 and a back heater volume 434. The front heater volume 435 includes the heating element 226 disposed therein. The front heater volume 435 is isolated from the back heater volume 434 by the reflector 410, such that the reflector 410 separates the front heater volume 435 from the back heater volume 434. The back heater volume 434 is either filled with an insulator, an inert gas, air, or is held at vacuum to reduce the heat transfer through the heater 168.

The reflector 410 may be a thermal isolator, such that the reflector 410 has a thermal conductivity of less than about 50 W/(m·K), such as less than about 10 W/(m·K), such as less than about 10 W/(m·K), such as less than about 5 W/(m·K), such as less than about 1 W/(m·K), such as less than about 0.5 W/(m·K), such as less than about 0.1 W/(m·K). The reflector 410 is further configured to reflect over 90% of radiant energy within an infrared wavelength range, such as a wavelength of about 700 nm to about 1 mm. The reflector 410 may be a ceramic or a dielectric material. In some embodiments, the reflector 410 is coated with a reflective coating to reflect radiation emitted by one or more lamps within the process chamber 100 or from the heating element 226. The coating may be a metal coating, such as an aluminum coating or a silver coating. In some embodiments, the reflector 410 is a reflective quartz material.

The heater casing 222 includes both a transmissive portion 414 and an opaque portion 416. The transmissive portion 414 is disposed around the heating element and within the heater insert body 402. The transmissive portion 414 is optically transparent, such that greater than about 90% of radiant energy within an infrared wavelength range, such as a wavelength of about 700 nm to about 1 mm, passes through the transmissive portion 414. In some embodiments, greater than about 95% of radiant energy in the infrared wavelength range pass through the transmissive portion 414, such as greater than about 98% of radiant energy. The transmissive portion 414 is formed of an optically transparent material, such as a transparent quartz material or glass.

The opaque portion 416 is a second portion of the heater casing 222 which is not disposed around the heating element 226. The opaque portion 416 is disposed on an opposite side of the reflector 410 from the transmissive portion 414. The opaque portion 416 extends through the flow module 112. The opaque portion 416 has a lower optical transparency than the transmissive portion 414, such that less than about 50% of radiant energy within an infrared wavelength range, such as a wavelength of about 700 nm to about 1 mm, passes through the transmissive portion 414. In some embodiments, less than about 30% of radiant energy within an infrared wavelength range passes through the transmissive portion, such as less than about 20%, such as less than about 10%, such as less than about 5%, such as less than about 2%.

A boundary 418 is disposed between the opaque portion 416 and the transmissive portion 414. The boundary 418 is disposed around the reflector 410, such that the reflector heater casing 222 transitions from the opaque portion 416 to the transmissive portion 414 at the reflector 410. The opaque portion 416 and the transmissive portion 414 are bonded, fused, welded, or brazed at the boundary 418. The transition to the opaque portion 416 from the transmissive portion 414 increases the proportion of the radiant energy emitted by the heating element 226 which is directed towards the first-pre heat ring portion 205 through the transmissive portion 414.

The formation of the entire heater casing 222 of a quartz material enables better bonding of the transmissive portion 414 and the opaque portion 416, such that the heater casing 222 is a single piece. Using a single piece for the heater casing 222 prevents leakage of process gas into one of the front heater volume 435 or the back heater volume 434 and simplifies installation of the heater 168.

The heating element 226 of FIG. 4A is a radiant heat source, such as a lamp 404. The bulb of the lamp 404 is disposed inside of the front heater volume 435. The lamp 404 may be similar to one of the upper lamps 141 or the lower lamps 143. The lamp 404 may alternatively be a smaller lamp, such that the bulb of the lamp 404 has a diameter of less than about 25 mm, such as less than about 20 mm. The lamp 404 has a power output of about 500 W to about 3000 W, such as about 500 W to about 1000 W, or such as about 1000 W to about 1500 W. Power is supplied to the lamp 404 by one or more electrical lines 412. The one or more electrical lines 412 are connected to a power source and/or the controller 120. The one or more electrical lines 412 are disposed through the reflector 410 and connected to the lamp 404. The base of the lamp 404 is also connected to the reflector 410, such that the bulb of the lamp 404 is directed away from the reflector 410 towards the process volume 136.

The heater base 224 includes a heater casing base 428, a compression cap 432 and a compression washer 430 disposed between the heater casing base 428 and the compression cap 432. The heater base 428 is formed of a similar material as the opaque portion 416 of the heater casing 222. In some embodiments, the heater base 428 is also bonded, fused, welded, or brazed to the opaque portion 416. In other embodiments, the heater base 428 is a single uniform and monolithic piece of the opaque portion 416. An outer wall 431 of the opaque portion 416 intersects a contact surface 427 of the heater base 428, such that the outer wall 431 of the opaque portion 416 is perpendicular and normal to the contact surface 427 of the heater base 428. The contact surface 427 is flush with an outer surface of the flow module 112 and contacts the outer surface of the flow module 112.

One or more grooves 425 are disposed within the contact surface 427. The one or more grooves 425 are annular grooves disposed around the opaque portion 416. The one or more grooves are sized to receive a seal heat shield 422 and a seal ring 426. The seal heat shield 422 is an insulator which reduces the heat transfer from the outer wall 431 of the opaque portion 416 to the seal ring 426 as the seal ring 426 fails at high temperatures. The seal heat shield 422 may be a ceramic or dielectric material and may be in either the same or a separate groove as the seal ring 426. The seal ring 426 is disposed radially outward from the seal heat shield 422 with respect to the outer wall 431 of the opaque portion 416.

The compression cap 432 is disposed on an outside surface of the heater base 224 relative to the heater casing 222. The compression cap 432 may be a metal material, such as an aluminum or steel. The compression cap 432 may have pressure applied thereto and may be coupled to the flow module 112, such that a portion of the compression cap 432 contacts the flow module 112 and one or more screws or bolts (not shown) are used to tighten the compression cap 432 against the outer surface of the flow module 112. The pressure from the compression cap 432 is distributed to the heater base 428 using the compression washer 430. The compression washer 430 is a metal or polymer material. In some embodiments, the compression washer 430 is the same material as the compression cap 432.

FIG. 4B is a schematic partial cross-sectional view of another heater 168 within the process chamber of FIG. 1. The heater 168 of FIG. 4B is similar to the heater 168 of FIG. 4A, but the heater 168 of FIG. 4B has a resistive heating element 450 as the heating element 226. The resistive heating element 450 is disposed within the front heater volume 435. The resistive heating element 450 is more compact than the lamp 404 utilized in the embodiment of FIG. 4A.

The resistive heating element 450 emits power at a rate of about 1000 W to about 3000 W, or such as about 500 W to about 1000 W, or such as about 1000 W to about 1500 W. The resistive heating element 450 has a resistance of greater than about 2 ohm (Ω), such as about 2Ω to about 100Ω.

As the resistive heating element 450 contacts and passes into the reflector 410, the resistivity of the heating element 450 decreases. The low resistance portion of the heating element 450 after passing through the reflector 410 is the heater power connector 452. The heater power connector 452 passes through the back heater volume 434. The heater power connector 452 is electrically coupled to a power source and/or the controller 120.

FIG. 4C is a schematic partial cross-sectional view of a heater 168 within the process chamber 100 of FIG. 1. The heater 168 of FIG. 4C is similar to the heater 168 of FIG. 4A, but the heater 168 of FIG. 4C also serves as the first pre-heat ring portion 205 of the pre-heat ring 166. Therefore, in the embodiment of FIG. 4C, a pre-heat ring 166 may be omitted or adapted to utilize the heater 168 and a corresponding heater block 250 in place of the first pre-heat ring portion 205.

The heaters and pre-heat ring assemblies described herein enable more accurate, rapid, and repeatable heating of a gas or precursor as the gas or precursor enters a process volume and before the gas or precursor passes over a substrate or a substrate support. By heating the gas or precursor to a higher temperature before the gas or precursor passes over the substrate, deposition on the substrate is generally increased over the entire width of the substrate and increased deposition is particularly high at a leading edge of the substrate.

While the foregoing is directed to embodiments of the present disclosure, other and further embodiments of the disclosure may be devised without departing from the basic scope thereof, and the scope thereof is determined by the claims that follow.

What is claimed is:

1. A process chamber, configured for use during semiconductor processing, comprising:
a chamber body comprising a plurality of gas inlets on a first side of the chamber body and one or more exhaust outlets on a second side of the chamber body opposite the first side;
a substrate support disposed within a process volume of the chamber body; and
a pre-heat ring assembly disposed between the plurality of gas inlets and the substrate support and comprising:
a pre-heat ring;
one or more heaters disposed adjacent to the pre-heat ring; and
one or more temperature sensors disposed adjacent to the pre-heat ring.

2. The process chamber of claim 1, wherein the pre-heat ring circumscribes the substrate support and further comprises:
a first pre-heat ring portion forming a first partial ring adjacent to the one or more heaters and the one or more temperature sensors and circumscribing a first portion of the substrate support; and
a second pre-heat ring portion forming a second partial ring and circumscribing a second portion of the substrate support different from the first portion.

3. The process chamber of claim 1, wherein the one or more heaters are coupled to a lower side of the pre-heat ring and the pre-heat ring rests on top of the one or more heaters.

4. The process chamber of claim 3, wherein the heaters further comprises:
a heater insert body;
a heater casing disposed at least partially within the heater insert body;
a reflector disposed within the heater casing and forming a front heater volume; and
a heating element disposed within the front heater volume of the heater casing.

5. The process chamber of claim 4, wherein the heating element is one of a lamp or a resistive heating element.

6. The process chamber of claim 4, wherein a heater base is coupled to an outside surface of the chamber body and coupled to the heater casing.

7. The process chamber of claim 1, further comprising:
a first plurality of lamps disposed above a first window; and
a second plurality of lamps disposed below a second window.

8. A pre-heat ring assembly, configured for use within a semiconductor processing chamber, comprising:
a pre-heat ring comprising a first pre-heat ring section and a second pre-heat ring section;
one or more temperature sensors coupled to the first pre-heat ring section; and
two or more heaters coupled to and configured to heat the first pre-heat ring section and comprising:
a heater casing;
a reflector disposed within the heater casing and forming a front heater volume;
a heating element disposed within the front heater volume.

9. The pre-heat ring assembly of claim 8, wherein the first pre-heat ring section is formed of a silicon carbide material.

10. The pre-heat ring assembly of claim 8, wherein the two or more heaters are disposed at least partially within a heater insert body and the first pre-heat ring section is disposed on top of the heater insert body.

11. The pre-heat ring assembly of claim 10, wherein the heater insert body is formed of a silicon carbide material.

12. The pre-heat ring assembly of claim 8, wherein heater casing is formed of a quartz material.

13. The pre-heat ring assembly of claim 12, wherein the heater casing further comprises:
a transmissive portion disposed around the heating element; and
an opaque portion coupled to a distal end of the transmissive portion.

14. The pre-heat ring assembly of claim 8, wherein one or more temperature sensors are disposed within the first pre-heat ring section.

15. A heater insert, configured to heat a pre-heat ring within a semiconductor processing chamber, comprising:
a heater casing comprising:
a transmissive portion;
an opaque portion coupled to a distal end of the transmissive portion; and
a heater base coupled to a distal end of the transmissive portion opposite the transmissive portion, such that the opaque portion intersects a contact surface of the heater base and the contact surface has one or more grooves disposed therein;
a reflector disposed within the heater casing and forming a front heater volume and a back heater volume; and
a heating element disposed within the front heater volume and within the transmissive portion of the heater casing.

16. The heater insert of claim 15, wherein the heating element is one of a lamp or a resistive heating element.

17. The heater insert of claim 16, wherein the heating element has a power output of about 500 W to about 3000 W.

18. The heater insert of claim 15, wherein the transmissive portion is a transmissive quartz with a transparency of greater than about 90% and the opaque portion is an opaque quartz with a transparency of less than about 50%.

19. The heater insert of claim 15, wherein the one or more grooves are configured to hold a heat shield ring and a sealing ring.

20. The heater insert of claim 15, wherein a compression washer and a compression cap are coupled to the heater base, such that the compression washer is disposed between the compression cap and the heater base.
